(19) United States
(12) Patent Application Publication
(10) Pub. No.: US 2017/0345780 A1
(43) Pub. Date: Nov. 30, 2017

(54) Surface Conditioning And Material Modification In A Semiconductor Device

(71) Applicant: Texas Instruments Incorporated, Dallas, TX (US)

(72) Inventors: Murlidhar Bashyam, Richardson, TX (US); Richard Allen Faust, Dallas, TX (US)

(21) Appl. No.: 15/162,867

(22) Filed: May 24, 2016

(51) Int. Cl. H01L 23/00

(52) U.S. Cl. CPC H01L 24/03; H01L 24/05; H01L 2224/05655; H01L 2224/05562; H01L 2224/05147; H01L 2224/05022; H01L 2224/0381; H01L 2224/0362; H01L 2224/03616; H01L 2224/03614; H01L 2224/03466; H01L 2224/05664; H01L 2224/04042

(57) ABSTRACT

A plasma-based ashing process for surface conditioning and material modification to improve bond pad metallurgical properties as well as semiconductor device performance. Residue materials generated in a removal process at a process layer having recessed features with Ni—Pd surfaces are ashed in a plasma reactor to reduce defect count and improve surface conditioning associated with bond pads of the semiconductor device.

### FIELD OF THE DISCLOSURE

This disclosure relates generally to the field of semiconductor devices and the methods of fabrication thereof, and more particularly, without limitation, to a surface conditioning, modification and/or treatment methodology in a semiconductor device.

### BACKGROUND

Without limitation, the following is provided in the context of fabricating bond pads (sometimes also referred to as contact pads) by way of illustration. Connecting microelectronic components, in particular semiconductor chips or microelectromechanical components or systems (MEMS), etc. requires a process that can provide a low cost yet rugged, robust and reliable method of interconnection. Wire bonding is generally considered the most cost-effective and flexible interconnect technology, and is used to assemble the vast majority of semiconductor packages. It is the primary method of making interconnections between the integrated circuit (IC) and the package leadframe (LF) or printed circuit board (PCB) substrate during semiconductor device assembly. However, successful wire bonding is critically dependent upon the surface finish of both the component's bond pads and the substrate.

It is known that semiconductor devices may include metal layers forming bond pads that may suffer from detrimental processes such as oxidation, corrosion, etc., as well as from processes that lack sufficient cleanliness in certain aspects. One skilled in the art will appreciate that semiconductor devices, bonding connectors and processes for manufacturing these components constantly have to be improved with respect to achieving high performance, high reliability and lowering manufacturing costs.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In one aspect, an embodiment of a method operative in fabricating a semiconductor device is disclosed. The claimed method comprises, inter alia, creating a plurality of recessed features in a process layer of the semiconductor device, wherein the recessed features include a nickel-palladium (Ni—Pd) surface that can contain residual materials generated in creating the recessed features; and removing the residual materials from the Ni—Pd surfaces of the recessed features by subjecting or exposing the semiconductor device to a plasma of reactive ion species for a specific duration. In an example embodiment, the plasma may be formed of O₂-based plasma chemistry.

In another aspect, an embodiment of a bond pad structure for an integrated circuit, die or chip formed on a wafer or portion thereof is disclosed. The bond pad structure comprises, inter alia, a first layer primarily comprising copper, having connections to underlying circuitry, the first layer being at least partially overlain by a patterned protective overcoat (PO) layer, thereby leaving an exposed portion. A nickel-palladium (Ni—Pd) diffusion barrier layer is deposited over the exposed portion of the first layer, the Ni—Pd diffusion barrier layer operating to prevent the copper from reacting with materials which are bonded to the bond pad structure, wherein the Ni—Pd diffusion barrier layer is treated by a plasma ashing process for improved residue removal.

In a still further aspect, another embodiment of a bond pad structure for an integrated circuit comprises, inter alia, a first layer primarily comprising copper and having connections to underlying circuitry that is at least partially overlain by a patterned PO layer, thereby leaving an exposed portion. A diffusion barrier layer is overlain the first layer, the diffusion barrier layer having a thickness achieved by applying a chemical-mechanical polishing (CMP) process, wherein the diffusion barrier layer is treated by a plasma ashing process for improved residue removal, whereby CMP's residual particulate matter or other byproducts are removed by micro-incineration.

In an example embodiment, a diffusion barrier metal layer may be deposited using one of a vapor deposition process, a galvanic plating process and an electroless plating process, and subsequently polished off by a CMP process to remove excessive material, followed by a plasma ashing process for improved residue removal and surface conditioning. In still further embodiments, surface conditioning and material modification of the present invention may be applied to topside metallization process layers, backside metallization process layers, or both, and other process layers having recessed features created by CMP processes and the like.

In yet another aspect, an embodiment of a semiconductor fabrication method is disclosed. The claimed embodiment comprises, inter alia, forming a metallization layer including bond pad areas of a semiconductor device; forming a protective overcoat (PO) firm overlying the metallization layer; selectively etching the PO layer to expose the bond pad areas, thereby generating a patterned PO layer having recessed features; applying a diffusion barrier composition material on top of the patterned PO layer to fill the recessed features; polishing off the diffusion barrier composition material (e.g., excess material) to expose the recessed features having a diffusion barrier composition material layer with a selective thickness over the bond pad areas; and applying a plasma ash process to incinerate residual materials left in the recessed features after the diffusion barrier composition material has been polished off.

### BRIEF DESCRIPTION OF THE DRAWINGS

Embodiments of the present disclosure are illustrated by way of example, and not by way of limitation, in the Figures of the accompanying drawings in which like references indicate similar elements. It should be noted that different references to “an” or “one” embodiment in this disclosure are not necessarily to the same embodiment, and such references may mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

The accompanying drawings are incorporated into and form a part of the specification to illustrate one or more exemplary embodiments of the present disclosure. Various advantages and features of the disclosure will be understood from the following Detailed Description taken in connection with the appended claims and with reference to the attached drawing Figures in which:

FIG. 1 illustrates an example flow of a surface treatment and/or modification process in semiconductor fabrication according to an embodiment of the present invention;

FIG. 2 illustrates an example flow of bond pad surface treatment/modification according to an embodiment of the present invention;

FIGS. 3A-3D illustrate cross-sectional schematic views an example process flow that may be employed in an embodiment of the present invention for creating a patterned protective overcoat layer having recessed features (e.g., bond pads, etc.) therein;

FIGS. 4A-4D illustrate cross-sectional schematic views of an example process flow that may be employed in an embodiment of the present invention for creating metallic bond pads overlain with one or more diffusion barrier layers;

FIG. 5 depicts a cross-sectional view of a portion of a semiconductor device (e.g., formed as part of a semiconductor die or wafer) wherein residual contaminants are treated by employing an example process flow of the present invention according to an embodiment; and

FIG. 6 depicts a graph of defect count reduction achieved in an example surface conditioning and modification process using plasma ash according to an embodiment of the present invention;

### DETAILED DESCRIPTION OF THE DRAWINGS

The present invention is described with reference to the attached Figures wherein like reference numerals are generally utilized to refer to like elements throughout. The Figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

In the following description, reference may be made to the accompanying drawings wherein certain directional terminology, such as, e.g., “upper”, “lower”, “top”, “bottom”, “left-hand”, “right-hand”, “front side”, “backside”, “vertical”, “horizontal”, etc., may be used with reference to the orientation of the Figures or illustrative elements thereof being described. Since components of embodiments can be positioned in a number of different orientations, the directional terminology is used for purposes of illustration and is in no way limiting. It is understood that further embodiments may be utilized and structural or logical changes may be made without departing from the scope of the present invention. The features of the various exemplary embodiments described herein may be combined with each other unless specifically noted otherwise.

As employed in this specification, the terms “coupled”, “electrically coupled”, “connected” or “electrically connected” are not meant to mean that elements must be directly coupled or connected together. Intervening elements may be provided between the “coupled”, “electrically coupled”, “connected” or “electrically connected” elements.

Example semiconductor devices described below may include or formed of a semiconductor material like Si, SiC, SiGe, GaAs or an organic semiconductor material. The semiconductor material may be embodied as a semiconductor wafer or a semiconductor chip containing any type of ICs, for example including but not limited to, digital, analog, mixed-signal, or power semiconductor chips. An example semiconductor chip or die may include integrated circuits, control circuits to control integrated circuits, microprocessors and/or microelectromechanical components or systems (MEMS), inter alia. The semiconductor chip may further include inorganic and/or organic materials that are not semiconductors, for example, insulators such as dielectric layers, plastics or metals, etc.

Examples of semiconductor devices fabricated using surface conditioning, modification or other treatments described below may include a plurality of bonding pads (also referred to as contact pads or bond pads) which may be made of or include a metal, e.g., copper, aluminum, etc., and may further comprise one or more layers of diffusion barrier layers. The contact pads may be configured to provide electrical connections between an integrated circuit of the semiconductor device and respective connecting elements connected to the contact pads. Possibilities to contact the contact pad include soldering, wire bonding, clip bonding, flip chip mounting and probe needles, among others. The connecting element may thus be embodied as a bonding wire or a bonding clip in some example embodiments.

Example bonding wires that may be bonded to contact pads that have had surface conditioning processes described below may include a wire core which may include a metal or a metal alloy, e.g., a copper or a copper alloy. The wire diameter may have a thickness ranging from less than a micron to several hundred microns, depending on application. In an example embodiment, wire diameters may be between 15 to 250 microns depending on a particular application. The wire core may have a substantially circular cross section such that term “thickness” of the wire core may refer to the diameter of the wire core.

Example bonding wires that may be bonded to contact pads that have had surface conditioning processes described below may further include a coating material arranged over the wire core. For example, an embodiment may include a coating material comprising one of niobium, tantalum, an alloy comprising niobium and tantalum, palladium-coated materials (e.g., Pd-coated copper or PCC), and the like. The properties of some of the coating materials (physical and chemical properties, thickness, etc.) may correspond to the properties of similar layers set forth herein.

The bonding wires or materials that may be bonded to contact pads of the present invention may include a passivation layer, for example, an oxide layer. In this connection, the term “passivation” may refer to avoiding or inhibiting oxidation and corrosion of a material sheathed by or arranged underneath the passivation layer. For example, the passivation layer may be generated via a spontaneous formation of a hard non-reactive surface film (spontaneous passivation). The passivation layer may have a thickness between 1 and 10 nm, in particular, between 4 and 8 nm in some example embodiments.

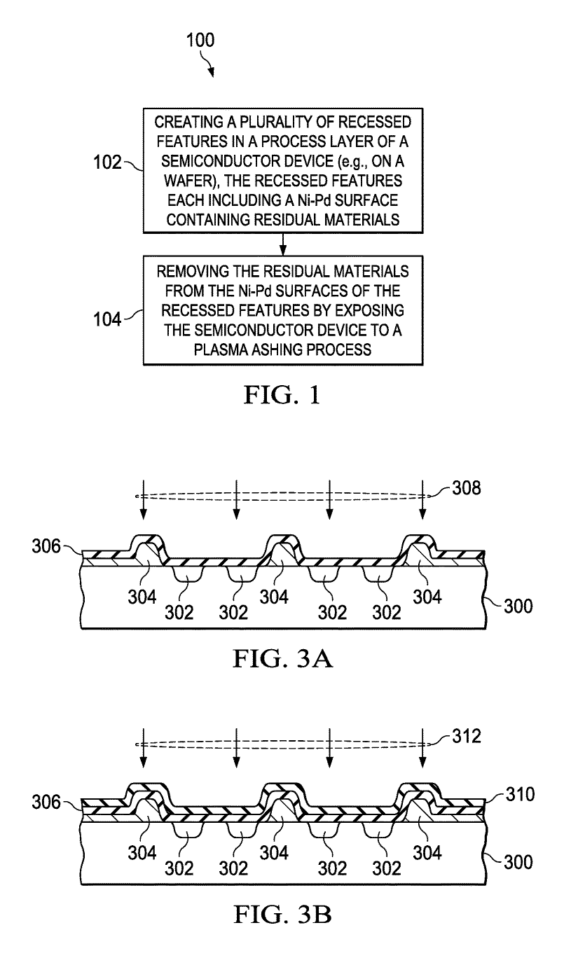

Referring now to the drawings and more particularly to FIG. 1, depicted therein is an example flow of a surface treatment and/or modification process 100 in semiconductor fabrication according to an embodiment of the present invention. One skilled in the art will appreciate that adhesion and/or bonding between material surfaces of process layers in a semiconductor fabrication flow, e.g., including adhesion between bond pads and respective electric connectors of a die, may be controlled by factors such as cleanliness, surface tension, topography, as well as the chemistry and wettability of the adherents. Several processing steps in an exemplary semiconductor fabrication flow may involve creating, generating, or otherwise patterning a number of recessed features in a process layer using a variety of techniques such as photolithography, etching, polishing, rinsing, etc. applied to the semiconductor device, e.g., a die being fabricated on the wafer. Although various precautions may be taken to keep the patterned process layer as clean as possible, the topography of the layer, including the recessed features, may still contain several undesirable residual materials, including processing byproducts, foreign particulates, organic/inorganic compounds, solvents, left over slurries, etc. (broadly referred to as “residual matter”) that can negatively impact physical, chemical and electrical properties (e.g., where metallization layers are involved) of the processed layer. For example, in an embodiment of a semiconductor fabrication process, a plurality of recessed features in a process layer of the semiconductor device may be created, wherein the recessed features include a nickel-palladium (Ni—Pd) surface that can contain residual materials generated in creating the recessed features, as set forth at block 102. According to the teachings of the present invention, the residual materials from the Ni—Pd surfaces of the recessed features may be advantageously removed by subjecting the semiconductor device or wafer to a plasma of reactive ion species for a specific in a controlled manner (block 104), which results in substantial improvement of the process layer surface in terms of reduced defects, better electrical parametrics (e.g., lower contact resistance), and the like, as will be set forth in additional detail hereinbelow by taking reference to one or more example embodiments of the present invention.

In an embodiment of the present invention, NiPd-based surface finish/metallization may be provided in combination with bond pad integration involving bond over active circuitry (BOAC) arrangements that are advantageous for carrying higher current densities by upper level metals. Typically, BOAC arrangements are provided with extra thick Cu routing having sufficient dimensions capable of higher current that is not possible with Al bond pads. NiPd-based compositions are particularly advantageous in enabling bonding to BOAC-type bond pad structures without relying on intermetallic formation and avoiding copper oxidation issues, but instead relying on mutually miscibility bonding. Whereas Pd may be added to protect the Ni (e.g., from oxidation), Pd can be reactive and catalytic in some instances, however. To help alleviate the reactivity or catalytic nature of the Pd surface and thus enable improved bonding, a plasma ashing process in accordance with the teachings of the may be implemented, with the additional advantages of surface conditioning as set forth herein.

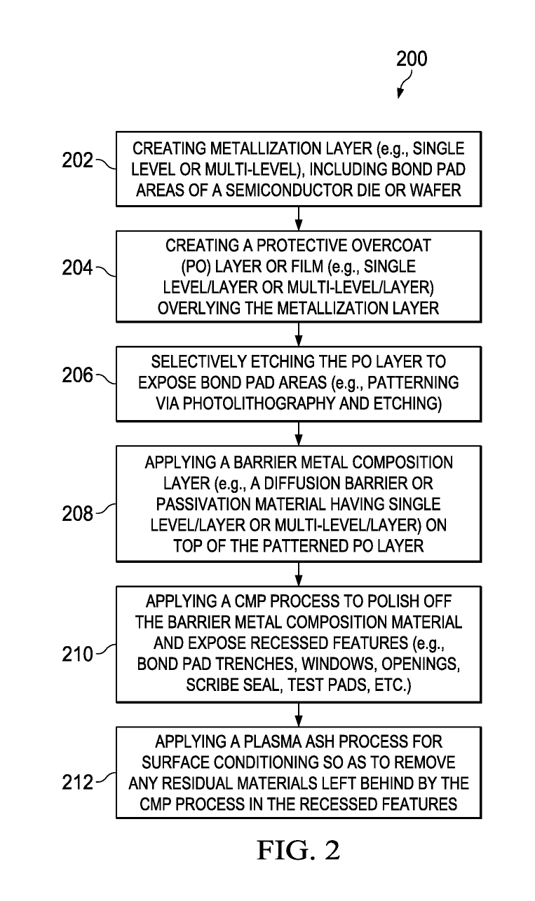

FIG. 2 is an example flow 200 of bond pad surface treatment/modification according to an embodiment of the present invention, which may be provided as a particularized implementation of the process set forth above. At block 202, a metallization layer (e.g., single level or multi-level) including bond pad areas of a semiconductor die or wafer may be created using any known or heretofore unknown metals, metallic compositions, and the like. A protective overcoat (PO) layer or film comprising one more layers/sub-layers of known or heretofore unknown dielectric and/or moisture barrier materials (e.g., oxides, nitrides, oxynitrides, polyimides, etc.) may be created or deposited overlying the metallization layer (block 204). Thereafter, the PO layer may be patterned (e.g., by photolithography and selective etching) to expose bond pad areas as well as other metallic features of the wafer scribe or kerf, as set forth at block 206.

It should be appreciated that while aluminum bond pads have been the standard in the semiconductor industry for decades, more and more chip manufacturers are looking to copper as device sizes shrink because of improved RC characteristics, among others. One of the issues encountered with copper metallization, however, is that it is not optimal for bonding directly. Copper, unlike aluminum, does not form a self-passivating oxide. When aluminum or gold wires are bonded to the copper, intermetallics are formed which are more resistive and which expand volumetrically, causing cracks and lowering reliability. One solution to this has been to form a barrier layer over the copper bond pad, which barrier layer may comprise multiple sub-layers, topped by a topmost layer that provides suitable physiochemical and electrical properties, allowing it to be bonded to a variety of bonding connector materials using known technologies. Accordingly, in one embodiment, a barrier metal composition layer (also referred to as a diffusion barrier or metal passivation layer) may be formed overlying the patterned PO layer (block 208), wherein a variety of metals, metallic compositions (e.g., including metal oxides, metal nitrides, etc.) may be applied using several techniques such as, e.g., galvanic electroplating, electroless plating, physical vapor deposition (PVD), sputter deposition, and the like. Example metals and metallic compositions or alloys that may be used for forming a diffusion barrier layer structure for the bond pads may include but not limited to: tantalum nitride (TaN), nickel (Ni), palladium (Pd), titanium nitride (TiN), and titanium (Ti), tungsten (W), titanium-tungsten, Cu—Ti, NiPd(Au), tungsten nitride (W—N), titanium silicon nitride (Ti—Si—N), tantalum silicon nitride (Ta—Si—N), cobalt (Co), chromium (Cr), molybdenum (Mo), etc. as well as any combinations thereof in various stoichiometric ratios, that operates to prevent intermetallic formation by impeding the up-diffusion of copper from the bond pads.

In general, a suitable diffusion barrier metal or composition may be deposited or otherwise applied over the wafer, overfilling the various recessed features patterned into the PO layer. Thereafter, a removal process may be applied, e.g., a chemical-mechanical polish (CMP) process, to remove excess diffusion barrier material, thereby leaving/forming a diffusion barrier layer or cap of certain desired thickness over the copper bond pads.

In one example implementation, a CMP process may use an abrasive/corrosive chemical slurry (commonly a colloid) in conjunction with a polishing pad and retaining ring, typically of a greater diameter than the wafer. The pad and wafer are pressed together by a dynamic polishing head and held in place by a plastic retaining ring. The dynamic polishing head may be rotated with specific axial geometry to remove the excess barrier metal composition and expose the recessed features (e.g., trenches, windows, openings for the bond pads, scribe seal, test pads, scribe marks, etc.), as set forth at block 210. The slurry for the CMP process may contain oxidizing or hydroxylating agents as well as mechanical polishing components for metals which may be not readily oxidized under normal conditions. In order to minimize undesired scratches or other deformities of the underlying copper or dielectric layers, a combination of buffers and soft poromeric pads may be used in one example implementation. Alternatively or additionally, organic buffers may be used in still further embodiments.

A wet cleaning process may be employed afterwards in order to remove the residual slurry byproducts and other materials of a CMP process. However, it should be appreciated that such wet processes are not efficient enough in removing the residual matter from the patterned PO layer, thereby negatively impacting the bond pad surface conditioning, e.g., increased defect counts and particulates as well as higher contact resistance to external connectors (e.g., wire-bonding connectors). Furthermore, the residual matter in narrower or smaller features (e.g., scribe seal, small test pads and miscellaneous scribe marks, etc.) may get packed with the slurry materials that are even more resistant to cleaning because of compaction upon drying. In accordance with the teachings herein, a plasma ash process may be applied (block 212) in addition to or in lieu of a wet process in order to improve the surface conditioning of the bond pads as well as clean the narrower features, wherein a suitable plasma chemistry may be designed with appropriate processing parameters, e.g., temperature profile, ranges of time, RF excitation frequencies and energies, pressure ranges, and the like, to micro-incinerate the residual matter in oxidative and/or reductive reactant species. For example, both low and medium temperatures as well as high temperature plasma environments may be employed, although high temperature ashing (e.g., 250° C. to 350° C.) may need to be followed by annealing of wafers. A typical low temperature plasma ashing process (e.g., 50° C. to 150° C.) of the present invention may not charge the wafer to such an extent that it requires annealing thereafter. In an example application, the plasma ash process of the present invention may therefore be practiced using a wide range of temperatures, from approximately 50° C. to 350° C.

In one example implementation, a plasma ashing process may be accomplished through the use of a low pressure, RF-induced gaseous discharge. The semiconductor wafer (or a plurality of wafers, if a batch process is deployed) may be loaded into a reaction chamber that is evacuated to a vacuum pressure to 0.1 to 0.2 torr by a mechanical vacuum pump. A carrier gas may be introduced into the chamber, raising the chamber pressure to 0.3 to 1.2 torr, depending on the application and chemistry. RF power (e.g., by way of a strong electromagnetic field at 13 to 15 MHz) may be applied around the chamber at a few hundred watts (e.g., 400 to 900 W), which dissociates the carrier gas molecules into chemically active ions and molecules (e.g., reactive ions or species such as monoatomic oxygen, etc. in certain plasma chemistries) by ionization, excitation and dissociation of the carrier molecules/atoms. Micro-incineration of the residual matter may typically result in common combustion products such as carbon oxides and water vapor at least with respect to organic moieties.

Several types of plasma ashers may be implemented in accordance with the teachings herein for purposes of surface conditioning, modification and treatment in semiconductor fabrication, which may vary considerably in terms of excitation frequency (e.g., 5 KHz to 5 GHz), operating pressure (e.g., 1 millibar to 1 atm), electrode arrangement, etc. In addition to barrel reactors, parallel plate reactors that are isotropic or anisotropic may also be employed. In a downstream plasma arrangement, reactive species may be generated at one place and carried downstream to a place or chamber or enclosure that houses the semiconductor wafer(s). Also, plasma ashers may be based on inductively coupled RF plasmas, capacitively coupled RF plasmas, electron cyclotron resonance plasmas, etc., wherein carrier gas chemistries may comprise or based on one or more of: O₂, Ar, H₂, He, N₂, C₂H₄, CH₄, C₂H₂, CF₄, SF₆, C₂F₆, CCl₄, O₂+H₂N₂, C₂Cl₆, SiF₄, and CO, etc.

Set forth below are further details with respect to one or more processes, sub-processes or steps described hereinabove, taking reference to additional example implementations that may be practiced in an embodiment of the present invention.

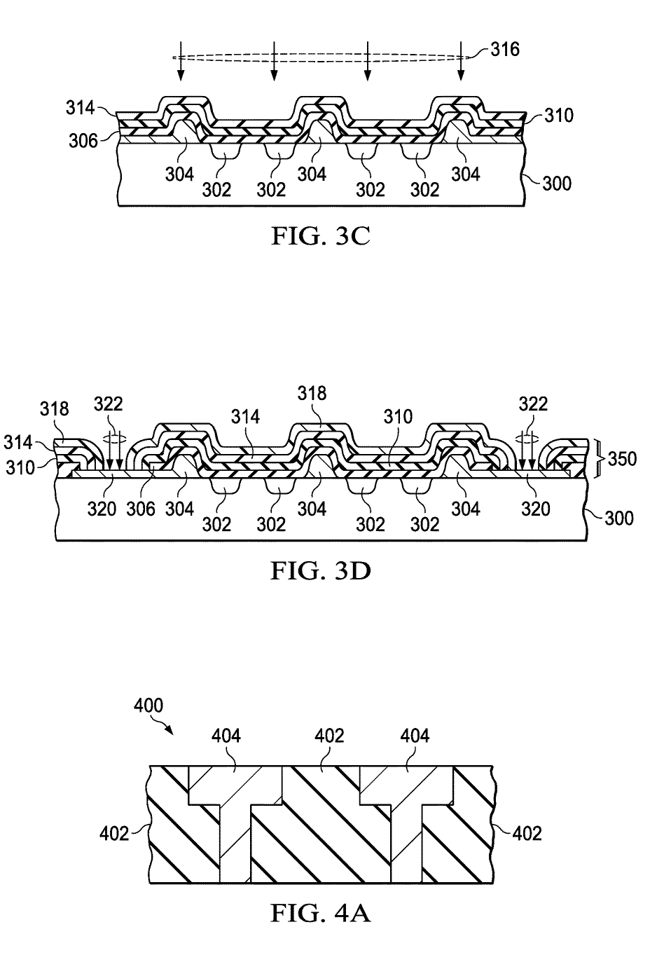

Turning to FIGS. 3A-3D, depicted therein are cross-sectional schematic views of an example semiconductor device or wafer portion that may be processed for purposes of an embodiment of the present invention wherein a completely inorganic patterned protective overcoat layer having recessed features (e.g., bond pads, etc.) therein may be created, generated or otherwise provided. In FIG. 3A, a silicon wafer or a portion thereof 300 having integrated circuits or portions thereof 302 patterned, including the topmost metal interconnection level 304 may be placed in a plasma enhanced chemical vapor deposition (PECVD) chamber. Using a standard PETEOS (plasma enhanced tetra ethyl ortho silicate) process designated by arrows 308, an oxide film 306 in an example range of several thousand Angstroms (Å) thick is deposited. In a more detailed view shown in FIG. 3B, the gas source may be changed to include silane and nitrogen and/or ammonia with the PECVD process designated by arrows 312 to deposit a film of silicon nitride 310 in an example range of 1,000 to 5,000 Å thick. The nitrogen sources may be removed, and in FIG. 3C another thin layer of oxide 314 is added using a standard PETEOS process 316, which may be substantially similar to the process 308 applied in FIG. 3A. The wafer is removed from the chamber, whereupon photoresist 318 is applied and patterned using photolithography to expose bond pads 320 and/or other openings required by the device being fabricated on the wafer 300. The pattern may preferably be etched using a gaseous dry etching process 322 to remove the protective overcoat layers from the bond pads, and other openings on the device. Alternatively, wet etching (e.g., with buffered hydrofluoric acid) may be used to etch the multilayer PO 350.

In another fabrication, a device having protective overcoat layers or silicon dioxide, silicon oxynitride, and silicon dioxide differs from that described above in that oxygen may be introduced along with nitrogen, silane, and ammonia curing the deposition process for the second layer (e.g., layer 310). The processes for silicon oxynitride are known and used throughout the industry for several types of IC fabrication. Processes for the first and third layers of the overcoat 350 may remain unchanged from that described above. Fabrication of protective overcoat of yet another embodiment including a layer of silicon dioxide, silicon carbide, and silicon dioxide differs from the embodiment of FIGS. 3A-3D in that silane/methane, trimethylsilane, tetramethylsilane, or other organosilane gas may be used as the source gas, along with Ar or He as a carrier gas, for the second layer 310 of silicon carbide. Again the first and third layers 306, 314 are of silicon dioxide using the PETEOS process.

Each of the processes for deposition and patterning is well known throughout the semiconductor industry, and the equipment is widely used. The combined successive processes form a unique PO structure having enhanced adhesion to polymers used in IC package assembly, as well as good adhesion between the film layers, and having minimal stresses on the circuits, thereby providing a strong, low defect, chip passivation. It should be appreciated that PECVD processing of successive overcoat layers eliminates excessive wafer handling by sequentially depositing layered films in a single chamber. Processes employing plasma enhanced chemical vapor deposition provide clean, uncontaminated surfaces between the layers as a function of the atmospheric control within the chamber, thus facilitating adhesion between the multiple layers. Further, PECVD optimizes process cycle time by successive depositions without handling, and by a single photopatterning step to etch openings. The completely inorganic overcoat set forth above for purposes of the present invention not only provides device performance advantages of enhanced adhesion to packaging polymers, but also has very high temperature stability, in excess of 450° C., and has improved thermal conductivity as compared to existing PO technology. In particular the embodiment having a silicon carbide second or barrier layer provides good thermal conductivity, and is applicable to high power circuits.

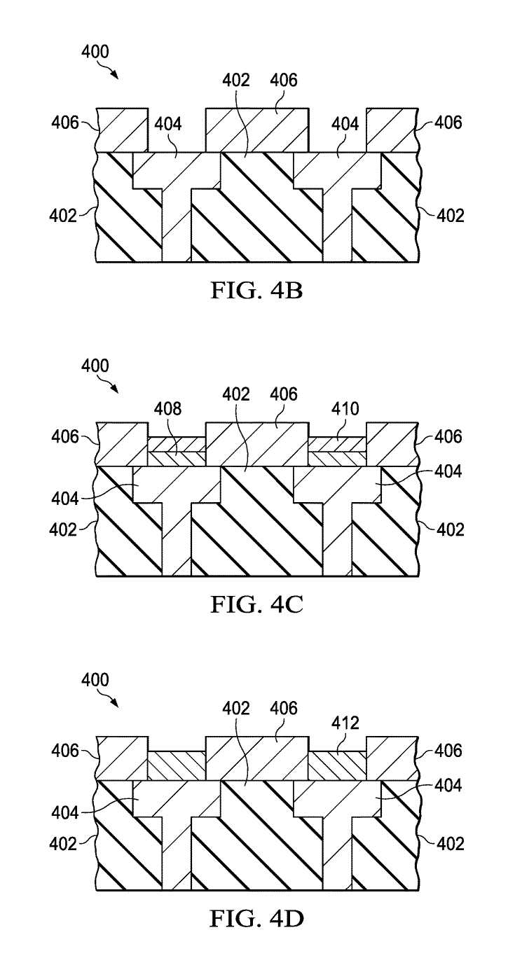

FIGS. 4A-4D are cross-sectional schematic views of an example semiconductor device or wafer portion that may be processed in accordance with an embodiment of the present invention for bond pad metallization including one or more diffusion barrier layers. One skilled in the art will recognize that the diffusion barrier metallization shown in FIGS. 4A-4D and the PO process of FIGS. 3A-3D may be suitably augmented or otherwise integrated, mutatis mutandis, within a process flow for creating metallic bond pads overlain with one or more diffusion barrier layers within the scope an embodiment of the present invention.

In one embodiment, exemplary process flow of FIGS. 4A-4D may take place during formation of the upper level of copper metallization of a semiconductor die or wafer or a portion thereof, generally shown at reference numeral 400. After deposition of an interlevel dielectric (ILD 402), a patterned etch may be used to form the trenches in the dielectric for all wiring desired on that level, including the desired bond pads. Another patterned etch may form the vias to lower wiring levels (not shown). Copper is then deposited to over-fill the vias and trenches, and excess copper is removed, e.g., by CMP, to form the wiring, including bond pads 404, as seen in FIG. 4A. Next, a protective overcoat (PO) layer 406 is formed, e.g., 200-300 nm of a high-density plasma chemical vapor deposited (HDPCVD) silicon nitride. A patterned etch is performed to open holes through the overcoat layer to expose the bond pads for external connections, giving rise to the structure shown in FIG. 4B, wherein at least a portion of the bond pad area may be overlain by the PO and the remainder forming an exposed portion. In another embodiment, PO layer 406 may comprise a multi-layer structure formed by a process such as shown in FIGS. 3A-3D described above. Finally, a metal passivation layer may be formed in the openings through the protective overcoat 406. Depending on the specific process used, this may be a self-aligning step, or may require a polish step to remove excess material. As noted previously, the metal passivation layer can be a single layer, or can comprise multiple layers which may be designed to give the protection needed for the underlying Cu bond pad structures. Once the passivation layer is completed, the bond pads are ready to receive the external connections, be they wire bonding, solder ball bonding or other types of boding. In one embodiment, a CuTix metallic composition may be provided as the diffusion barrier or passivation layer. In this embodiment, after exposing the bond pads through the protective overcoat, a thin layer of titanium (Ti) may be deposited to a depth of approximately 10-60 nm thick over the surface. During an anneal, the titanium reacts with the copper to form CuTix, an inert intermetallic which will prevent further reaction of the copper. After an annealing step, the unreacted titanium is removed from the surface of the chip.

In another embodiment, a CuTix/TiN combination may be provided as the diffusion barrier layer. In this embodiment, after deposition of titanium, the semiconductor chip or wafer may be exposed to an ambient which contains either nitrogen or ammonia. During the anneal, the upper surface of the titanium will react with the nitrogen present to form a layer of TiN 410 while the lower surface of the titanium reacts with the copper to form CuTix 408. After the unreacted titanium is removed from the surface of the chip, FIG. 4C shows the resulting bond pad structure.

Yet another embodiment may involve deposition of TiN for passivation and diffusion barrier. Here, a layer of TiN 412 is deposited over the chip, overfilling the holes through the PO 406. A CMP step removes excess material outside of the holes, giving rise to the structure shown in FIG. 4D. In still further embodiments, other passivation materials may be employed to prevent reaction of the copper and aluminum, such as, e.g., tungsten nitride, tantalum nitride, titanium silicon nitride, tungsten silicon nitride, and tantalum silicon nitride, as noted previously. Like TiN, these materials will fill the holes through the protective overcoat 406, with the excess being polished off by CMP.

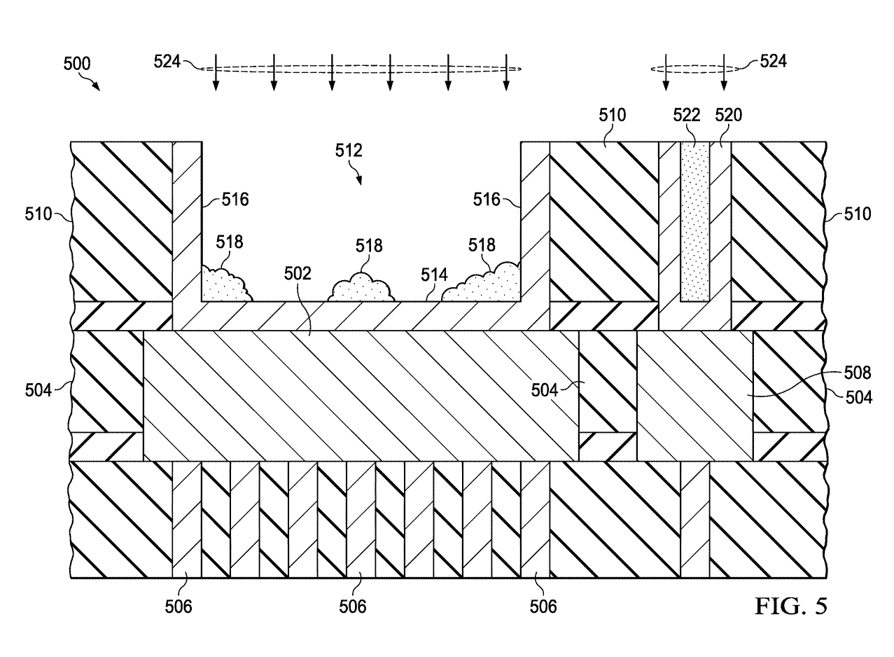

Turning now to FIG. 5, depicted therein is a cross-sectional view of a portion of a semiconductor device or portion 500 (e.g., formed as part of a semiconductor die or wafer) wherein residual contaminants may be treated by employing an example process flow of the present invention according to an embodiment. Portion 500 exemplifies a structure comprising a Cu bond pad 502 (e.g., approximately 50 to 300 microns wide) which may be formed in an ILD 504, wherein the bond pad 502 may be electrically connected to other metallic interconnections of the device by way of a plurality of metallic vias 506 as set forth hereinabove. Illustratively, a scribe seal structure or feature 508 that is dielectrically isolated from bond pad 502 is also exemplified. A dielectric PO layer 510 having a thickness of several Angstroms (e.g., 2,000 to 32,000 Angstroms) that includes one or more layers of a composition selected from silicon nitride, silicon oxide, oxynitride, polyimide, and the like may be overlain and patterned as described previously in one example embodiment. A multi-level/layer Cu diffusion barrier metal, e.g., comprising TaN—Ni—Pd, Ni—Pd, and the like, may be applied in a multistep process over the patterned PO layer 510. At a suitable CMP process, the excess diffusion barrier metal may be polished off as described above, resulting in PO dielectric layer 510 having a desirable thickness range, including various recessed features, e.g., recessed feature 512 corresponding to the bond pad 502 and other structures (e.g., a narrow feature 520 corresponding to scribe seal 508 as well as respective recessed features corresponding to small test pads, scribe marks, etc. that are not specifically shown in FIG. 5). It should be appreciated that the CMP process may be performed using a variety of slurries depending on the specific fabrication process, preferably until a desirable thickness for the diffusion barrier layer that overlies the Cu bond pad 502 is achieved. In an example embodiment, the diffusion barrier layer or surface may be thicker or thinner, depending on a particular application, e.g., from about 50 to 1,000 Angstroms or thereabouts. Whereas the bottom portion or surface 514 of the diffusion barrier well that lines the Cu bond pad 502 may have the desired thickness, sidewall portions or surfaces 516 of the diffusion barrier layer of recessed feature 512 may be thinner, however. Both wider recessed features 512 corresponding to bond pads as well as narrow recessed features 520 corresponding to other structures may contain residual matter comprising left over slurry or byproducts that are difficult to be rinsed away, as noted previously. In particular, the residual matter remaining in the narrow recessed features 520 may become hardened and completely block the cavity of the feature altogether, which can be particularly resistant to wet clean. By way of illustration, reference numeral 518 refers to materials illustrative of residual matter in the recessed feature 512 and reference numeral 522 refers to materials illustrative of potentially packed/compacted residual matter in the recessed feature 520.

In one example process, the residual materials comprise one or more of: quaternary ammonium ions (N(CₓH_{y})₄ ions), aryl ester, dioctyl phalate (DOP), Pd(NH₃)x, bromine, benzotriazole (BTA), PdO, sodium lauryl sulfate, and other detergent compounds, as well as other organic and/or inorganic compounds or compositions. A plasma ash treatment, as shown by arrows 524 may involve any type of plasma ashing processes, chemistries, process parameters, reactor types, and the like, described hereinabove, with suitable optimizations or customizations depending on the particular semiconductor product and fabrication process. In certain example embodiments, the inventors of the present invention have used O₂-based ashing for durations of 150 s to 250 s for main ash, with significant improvement in physical and chemical properties as well as electric/parametric data in test wafer splits.

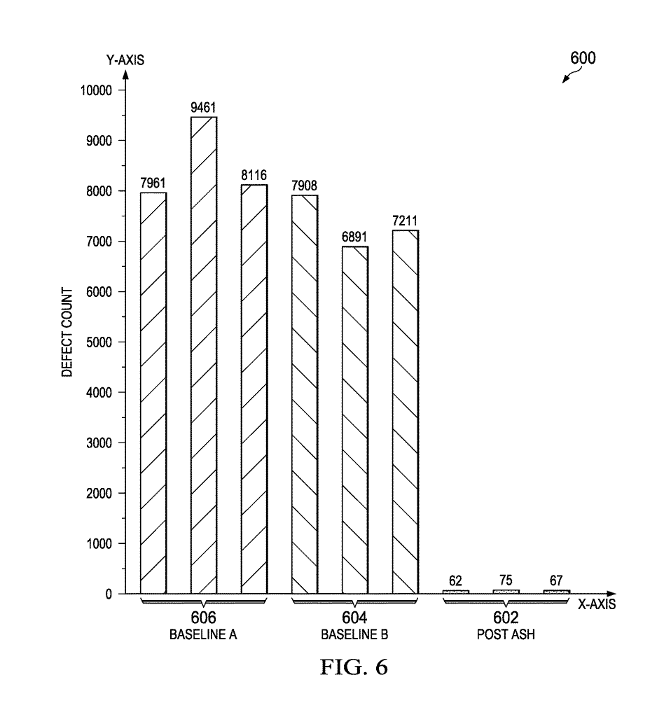

FIG. 6 depicts a graph 600 of defect count reduction achieved in an example surface conditioning and modification process using plasma ash according to an embodiment of the present invention. It can be seen that a test split 602 comprising post-ash wafers shows a considerable reduction in the total defect count (e.g., particles, scratches, or other deformities, etc.) compared to baseline splits 604 and 606. The inventors of the present invention have also obtained favorable results using various test splits with respect to wafers treated with one or more embodiments of the present invention wherein contact resistance (CRES) and visual inspection of residual particles, contaminants and other defects have been improved over baseline splits.

Based on the foregoing Detailed Description, one skilled in the art will appreciate that example embodiments relating to surface conditioning and material modification advantageously provide improved metallurgical properties as well as enhanced device performance. In the context of the present patent application, it should be understood that “material modification” in an example embodiment may comprises process steps relating to removal/incineration, using a O₂ (or other) dry ash, of any foreign/unwanted residual matter or impurities left behind in the wake of a CMP process applied after the diffusion barrier metal deposition, thereby altering the bond pad contact surface, e.g., its electrical properties, adhesion properties, etc. There may also be chemical altering of the barrier metal composition(s) (e.g., where O₂ ash is implemented, a metal oxide may be formed). Further, as oxidative ashing can also oxidize a topside metal of a diffusion barrier, e.g., Ni, Pd, etc., beneficial effects may include reduced corrosion in topside acid tests (e.g., more resistant to damaging acids such as nitric acid used in further downstream steps). As plasma treatment processes are generally more benign than wet clean processes, it is envisaged that overall fabrication process flow of a semiconductor foundry is also enhanced.

Although various embodiments have been shown and described in detail, the claims are not limited to any particular embodiment or example. None of the above Detailed Description should be read as implying that any particular component, element, step, act, or function is essential such that it must be included in the scope of the claims. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed by the present claims. Accordingly, those skilled in the art will recognize that the exemplary embodiments described herein can be practiced with various modifications and alterations within the spirit and scope of the claims appended below.

What is claimed is:

1. A method in fabricating a semiconductor device, the method comprising:
creating a plurality of recessed features in a process layer of the semiconductor device, wherein the recessed features include a nickel-palladium (Ni—Pd) surface that can contain residual materials generated in creating the recessed features; and
removing the residual materials from the Ni—Pd surfaces of the recessed features by subjecting the semiconductor device to a plasma of reactive ion species for a specific duration.

2. The method as recited in claim 1, wherein the recessed features are formed in a process layer comprising a protective overcoat (PO) layer overlying a metallization layer of the semiconductor device and at least a subset of the plurality of the recessed features comprise openings in the PO layer aligned to bond pads of the metallization layer.

3. The method as recited in claim 2, wherein the metallization layer comprises a copper metallization layer having copper bond pads.

4. The method as recited in claim 3, wherein the Ni—Pd surfaces are formed over the copper bond pads as a diffusion barrier film that is polished off using a chemical-mechanical polishing (CMP) process, generating the residual materials in the recessed features.

5. The method as recited in claim 4, wherein the diffusion barrier film further comprises a material selected from tantalum nitride, titanium nitride, and titanium.

6. The method as recited in claim 2, wherein the PO layer comprises a multi-layer film of 2,000 to 32,000 Angstroms in thickness that includes one or more layers of a composition selected from silicon nitride, oxynitride, silicon oxide and polyimide.

7. A bond pad structure for an integrated circuit, the bond pad structure comprising:
a first layer primarily comprising copper, having connections to underlying circuitry, the first layer being at least partially overlain by a patterned protective overcoat (PO) layer, thereby leaving an exposed portion; and
a nickel-palladium (Ni—Pd) diffusion barrier layer overlying the exposed portion of the first layer, the Ni—Pd diffusion barrier layer operating to prevent the copper from reacting with materials which are bonded to the bond pad structure, wherein the Ni—Pd diffusion barrier layer is treated by a plasma ashing process for improved residue removal.

8. The bond pad structure as recited in claim 7, wherein the Ni—Pd diffusion barrier layer comprises a multi-layer film of 50 Angstroms to 1,000 Angstroms in thickness and further includes one or more layers of a material selected from tantalum nitride, titanium nitride, and titanium.

9. The bond pad structure as recited in claim 7, wherein the first layer is dimensioned to receive a wirebonding connector operative with a wirebonding interconnect process using one of ball bonding, wedge bonding, ribbon bonding, clip bonding and tape-automated bonding (TAB).

10. The bond pad structure as recited in claim 7, wherein the Ni—Pd diffusion barrier layer is deposited using one of a vapor deposition process, a galvanic plating process and an electroless plating process, and subsequently polished off by a chemical-mechanical polishing (CMP) process.

11. A semiconductor fabrication method, comprising:
forming a metallization layer including bond pad areas of a semiconductor device;
forming a protective overcoat (PO) firm overlying the metallization layer;
selectively etching the PO layer to expose the bond pad areas, thereby generating a patterned PO layer having recessed features;
applying a diffusion barrier composition material on top of the patterned PO layer to fill the recessed features;
polishing off excessive diffusion barrier composition material to expose the recessed features having an overlain diffusion barrier composition material layer with a selective thickness over the bond pad areas; and
applying a plasma ash process to incinerate residual materials left in the recessed features after the diffusion barrier composition material has been polished off.

12. The semiconductor fabrication method as recited in claim 11, wherein the PO layer comprises a multi-layer film of 2,000 to 32,000 Angstroms in thickness that includes one or more layers of a composition selected from silicon nitride, oxynitride, silicon oxide and polyimide.

13. The semiconductor fabrication method as recited in claim 11, wherein the diffusion barrier composition material layer comprises a multi-layer film of 50 Angstroms to 1,000 Angstroms in thickness and includes one or more layers of a material selected from tantalum nitride, nickel, palladium, titanium nitride, and titanium that may be applied in one or several steps.

14. The semiconductor fabrication method as recited in claim 11, wherein the plasma ash process involves exposing the semiconductor device to a plasma chemistry based on one or more of: O₂, Ar, H₂, He, N₂, C₂H₄, CH₄, C₂H₂, CF₄, SF₆, C₂F₆, CCl₄, C₂Cl₆, SiF₄, O₂+H₂N₂, and CO.

15. The semiconductor fabrication method as recited in claim 14, wherein the plasma ash process involves ashing performed in a temperature range of 60° C. to 350° C.

16. The semiconductor fabrication method as recited in claim 14, wherein the plasma ash process is performed in one of a barrel reactor, a plasma plate reactor, and a downstream chamber reactor.

17. The semiconductor fabrication method as recited in claim 16, wherein the plasma ash process involves a plasma environment comprising one of a capacitively coupled RF plasma, an inductively coupled RF plasma and an electron cyclotron resonance plasma.

18. The semiconductor fabrication method as recited in claim 11, wherein the residual materials comprise one or more of: quaternary ammonium ions (N(CₓH_{y})₄ ions), aryl ester, dioctyl phalate (DOP), Pd(NH₃)x, bromine, benzotriazole (BTA), PdO, sodium lauryl sulfate, and other detergent compounds.

19. A bond pad structure for an integrated circuit, the bond pad structure comprising:
a first layer primarily comprising copper, having connections to underlying circuitry, the first layer being at least partially overlain by a patterned protective overcoat (PO) layer, thereby leaving an exposed portion; and
a diffusion barrier layer overlying the exposed portion of the first layer, the diffusion barrier layer having a thickness achieved by applying a chemical-mechanical polishing (CMP) process, wherein the diffusion barrier layer is treated by a plasma ashing process for improved residue removal.

20. The bond pad structure as recited in claim 19, wherein diffusion barrier layer is deposited using one of a vapor deposition process, a galvanic plating process and an electroless plating process, and subsequently polished off by the CMP process.

21. The bond pad structure as recited in claim 20, wherein the diffusion barrier layer comprises a multi-layer film of 50 Angstroms to 1,000 Angstroms in thickness and includes one or more layers of a material selected from tantalum nitride, nickel, palladium, titanium nitride, and titanium.

22. The bond pad structure as recited in claim 19, wherein the first layer is dimensioned to receive a wirebonding connector operative with a wirebonding interconnect process using one of ball bonding, wedge bonding, ribbon bonding, clip bonding and tape-automated bonding (TAB).
